(19) United States
(12) Patent Application Publication
(10) Pub. No.: US 2015/0215043 A1
(43) Pub. Date: Jul. 30, 2015

(54) Lasers Based On Optical Ring-Resonators

(71) Applicant: Alcatel-Lucent USA Inc., Murray Hill, NJ (US)

(72) Inventor: Helene Francoise Debregeas, Summit, NJ (US)

(73) Assignee: ALCATEL-LUCENT USA INC., Murray Hill, NJ (US)

(21) Appl. No.: 14/168,521

(22) Filed: Jan. 30, 2014

(51) Int. Cl. H04B 10/2575; G01J 3/453; H04B 10/61; H01S 5/12; H04J 14/02; G01J 3/45; H01S 5/10

(52) U.S. Cl. CPC H04B 10/2575; G01J 3/45; G01J 3/453; H01S 5/1071; H01S 5/124; H04J 14/02; H04B 10/61; G01J 2003/4534

(57) ABSTRACT

An apparatus includes a laser that includes an optical gain medium and first and second optical ring-resonators. The optical gain medium and the optical ring-resonators are serially optically connected together to form one or more segments of an optical cavity of the laser. One of the optical ring-resonators has a Mach-Zehnder interferometer forming an internal optical waveguide segment of the one of the optical ring-resonators.

### BACKGROUND

1. Technical Field

The inventions relate to lasers, methods of operating lasers, and systems including one or more lasers.

2. Related Art

This section introduces aspects that may be helpful to facilitating a better understanding of the inventions. Accordingly, the statements of this section are to be read in this light and are not to be understood as admissions about what is in the prior art or what is not in the prior art.

A broadly tunable laser may use a semiconductor optical amplifier (SOA) that is end-connected to one or more planar lightwave circuits (PLC). For example, the SOA may use group 3-5 semiconductor technology while the PLC uses silica-based technology. In such a laser, the serial combination of the SOA and one or more PLCs forms the laser cavity, which may have reflectors at its two ends. In such a laser, the one or more PLCs may operate as a wavelength-selective passive optical filter that is configured to select one wavelength-mode of the cavity for lasing.

Coherent optical communication systems can use advanced modulation schemes to modulate data onto an optical carrier. In such schemes, an optical transmitter modulates data onto an optical carrier, in part, by modulating the phase of the optical carrier. In such schemes, an optical receiver typically recovers the data from such a phase-modulated optical carrier by optically interfering the phase-modulated optical carrier with a local reference optical carrier having approximately the same wavelength. In such an optical receiver, the intensity of the interfered light is typically detected, converted to a digital signal stream, and digitally processed.

### SUMMARY OF SOME EXAMPLE EMBODIMENTS

Herein, some embodiments provide lasers with narrow optical linewidths. Some such lasers may be advantageous for use in coherent optical communications systems and/or optical spectrum analyzers. For example, use of such lasers in an optical transmitter and/or a coherent optical receiver may enable improved demodulation of data by reducing phase noise in a data-modulated optical carrier and/or in light from a local optical oscillator. Alternatively, some such lasers may be operable to provide broadly tunable, narrow-band lasers, which are useful in optical spectrum analyzers, e.g., for identifying and/or analyzing chemical analyte samples.

In first embodiments, an apparatus includes a laser that includes an optical gain medium and first and second optical ring-resonators. The optical gain medium and the optical ring-resonators are serially optically connected together to form one or more segments of the optical cavity of the laser. One of the optical ring-resonators has a Mach-Zehnder interferometer forming an internal optical waveguide segment of the one of the optical ring-resonators.

In some of the above apparatus, the laser may further include a semiconductor optical amplifier, and the optical gain medium is located in the semiconductor optical amplifier.

In some embodiments of any of the above apparatus, the optical waveguide of one or both of the optical ring-resonators may be a dielectric optical waveguide.

In some embodiments, any of the above apparatus may further include a controller capable of tuning or both of the first and second optical ring-resonators such that the first and second optical-ring resonators have some coincident optical band passes and some non-coincident optical band passes.

In some embodiments, any of the above apparatus may further include a coherent optical data receiver, an optical data transmitter, or an optical spectrum analyzer. The coherent optical data receiver includes the laser and may be configured to determine a digital data stream carried by a phase and/or amplitude modulated optical carrier, in part, by optically mixing light of the phase and/or amplitude modulated optical carrier with light emitted by the laser. Some such coherent optical data receivers may be configured to feedback control an output wavelength of the laser based on measurements of the optically mixed light. The optical data transmitter includes the laser and an external optical modulator. The external optical modulator is configured to data modulate light emitted by the laser to produce a phase and/or amplitude modulated optical carrier. The spectral analyzer includes the laser and an optical detector. The optical detector is configured to measure one or more intensities of light directed to the optical detector by a sample in response to being illuminated by light of the laser, e.g., a chemical sample. Some such spectral analyzers may be configured to cause the laser to sweep, in time, an output wavelength of the laser.

In second embodiments, a method includes tuning a Mach-Zehnder interferometer to wavelength-shift peaks in a spectral transmittance of the Mach-Zehnder interferometer. The Mach-Zehnder interferometer forms an internal optical waveguide segment of a first optical ring-resonator. The first optical ring-resonator and a second optical ring-resonator are a serial optical combination in an optical cavity of a laser. The method also includes tuning the serial optical combination of the optical ring-resonators to wavelength-shift a coincidence between optical band passes of the optical ring-resonators to be at or near one of the peaks in the spectral transmittance of the Mach-Zehnder interferometer.

In some of the second embodiments of the method, the tuning of the serial optical combination may include tuning one of the optical ring-resonators to shift its optical band passes to be on a pre-selected optical channel grid. In some such embodiments, the preselected optical channel grid may be one of the ITU grids for optical communication channels of dense wavelength-division multiplexing. In some second embodiments of this paragraph, the method may include adjusting a total optical path length of the optical cavity such that a cavity mode thereof has an optical wavelength at about the optical wavelength of the coincidence of the optical band passes.

In some of the second embodiments, the method further includes either electrically or optically pumping an optical medium in the optical cavity such that the laser emits light. The optical gain medium may be located in a semiconductor optical amplifier.

In some of the second embodiments, the method further includes mixing a portion of light emitted by the laser with a received phase and/or amplitude modulated optical carrier to perform coherent detection of the phase-modulated optical carrier in a coherent optical receiver.

In some of the second embodiments, the method further includes then, data modulating light emitted by the laser in an optical data transmitter to produce an optical carrier that is at least phase modulated.

In some of the second embodiments, the method further includes re-tuning one or more of the first optical ring-resonator, the second optical ring-resonator and the Mach. Zehnder interferometer such that a wavelength of light emitted by the laser sweeps, in time, through a series of values.

In some of the second embodiments, the method further includes measuring intensities of light transmitted, reflected, or scattered by a sample in response to the sample being illuminated by the emitted light at the values of the wavelength of light emitted.

### BRIEF DESCRIPTION OF THE DRAWINGS

FIG. 1a is a block diagram schematically illustrating a first embodiment of a laser whose laser cavity includes a wavelength-selective optical filter;

FIG. 1b is a top view schematically illustrating a specific example of the first embodiment of a laser;

FIG. 2a is a block diagram schematically illustrating a second embodiment of a laser whose laser cavity includes a wavelength-selective optical filter;

FIG. 2b is a top view schematically illustrating a specific example of the second embodiment of a laser;

FIG. 3a is a block diagram schematically illustrating a third embodiment of a laser whose laser cavity includes a wavelength-selective optical filter;

FIG. 3b is a top view schematically illustrating a specific example of the third embodiment of a laser;

FIG. 4a is a block diagram schematically illustrating a fourth embodiment of a laser whose laser cavity includes a wavelength-selective optical filter;

FIG. 4b is a top view schematically illustrating a specific example of the fourth embodiment of a laser;

FIG. 5a qualitatively illustrates a hypothetical example for a desired relationship between the coincidences of two serially coupled, optical ring-resonators and a periodic envelope of an MZI internal to one of the optical ring-resonators, e.g., for use implementation in some lasers of FIGS. 1a-4b;

FIG. 5b plots a simulated spectral transmittance for an example fabrication and tuning of an optical ring-resonator with an internal MZI, e.g., for use in some lasers of FIGS. 1a-4b;

FIG. 5c plots a simulated spectral transmittance for an example fabrication and tuning of a serial optical combination of the optical ring-resonator of FIG. 5b and another optical ring-resonator, e.g., for use in some lasers of FIGS. 1a-4b;

FIG. 6 illustrates an optical data transmitter that includes a laser whose laser cavity includes a wavelength-selective optical filter, e.g., as in any of the lasers of FIGS. 1a-4b;

FIG. 7 illustrates a coherent optical data receiver that includes a laser whose laser cavity includes a wavelength-selective optical filter, e.g., as in any of the lasers of FIGS. 1a-4;

FIG. 8 illustrates an optical spectrum analyzer that includes a laser whose laser cavity includes a wavelength selective optical filter, e.g., any of the lasers of FIGS. 1a-4b; and

FIG. 9 schematically illustrates a method of tuning and/or operating a laser whose laser cavity includes a tunable wavelength-selective optical filter, e.g., any of the lasers of FIGS. 1a-4b.

In the Figures and text, like reference symbols indicate elements with similar or the same function and/or structure.

In the Figures, the relative dimensions of some features may be exaggerated to more clearly illustrate one or more of the structures therein.

In the Figures, some optical waveguides may be referenced with the letter O to improve the clarity of the illustrations.

Herein, various embodiments are described more fully by the Summary of the Example Embodiments, the Figures and the Detailed Description of Illustrative Embodiments. Nevertheless, the inventions may be embodied in various forms and are not limited to the embodiments described in the Summary of the Example Embodiments, the Figures, and Detailed Description of Illustrative Embodiments.

### DETAILED DESCRIPTION OF ILLUSTRATIVE EMBODIMENTS

Herein, some optical components have optical band passes or optical transmittance peaks that are regularly spaced in frequency. For such an optical component, the approximate frequency spacing between neighboring ones of said optical band passes or optical transmittance peaks will be referred to herein as the free spectral range (FSR) of the optical component. If the optical band passes or optical transmittance peaks of an optical component are regularly spaced over a reasonably broad frequency range, e.g., five or more neighboring ones of the optical band passes or optical transmittance peaks, the optical component will be referred to as having a FSR even if strengths of the optical band passes or optical transmittance peaks vary with frequency. Some optical components, having an FSR, have optical band passes or optical transmittance whose strengths vary strongly and/or rapidly with frequency, and other optical components, having an FSR, have optical band passes or optical transmittance peaks whose strengths vary only little and/or slowly with frequency over large frequency ranges.

### Examples of Lasers

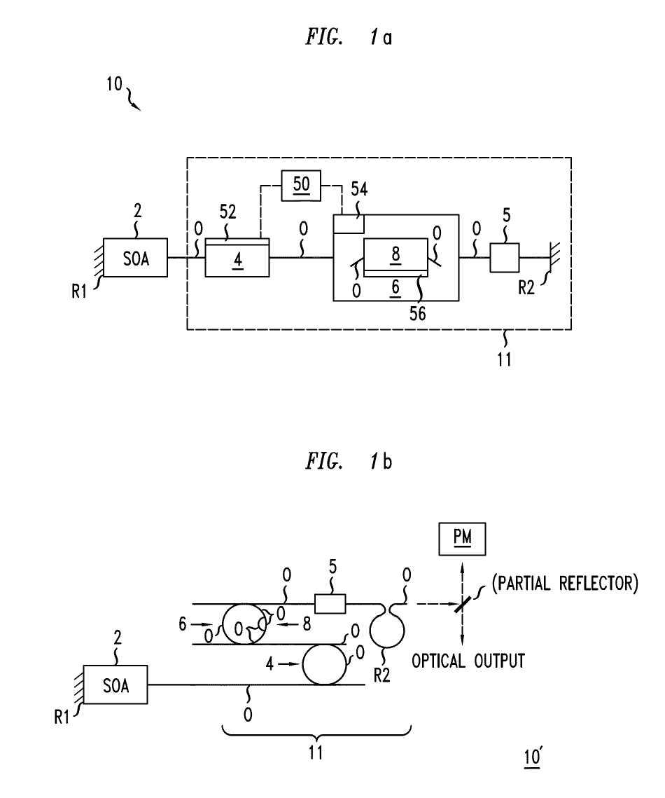

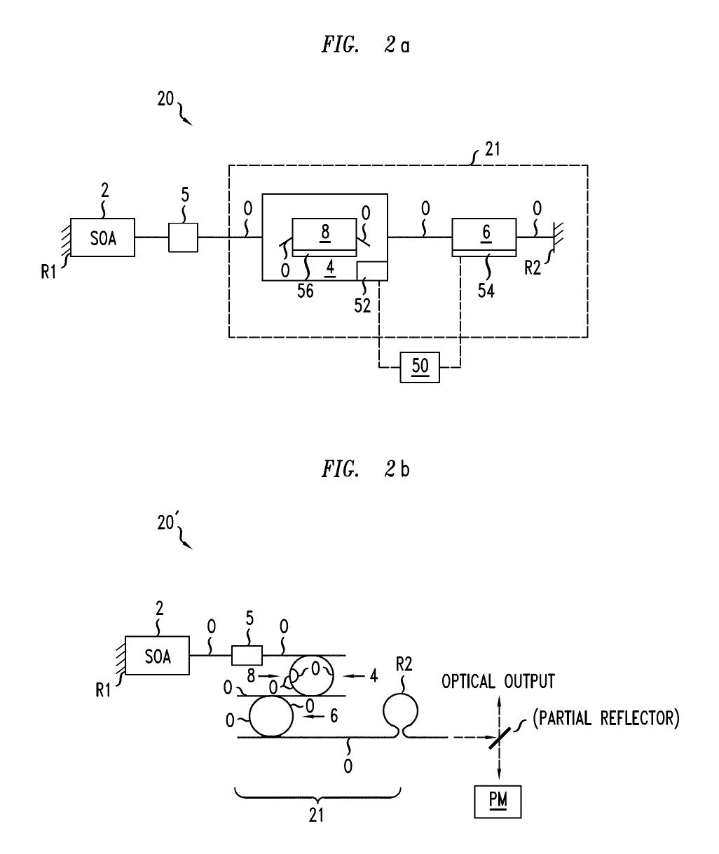

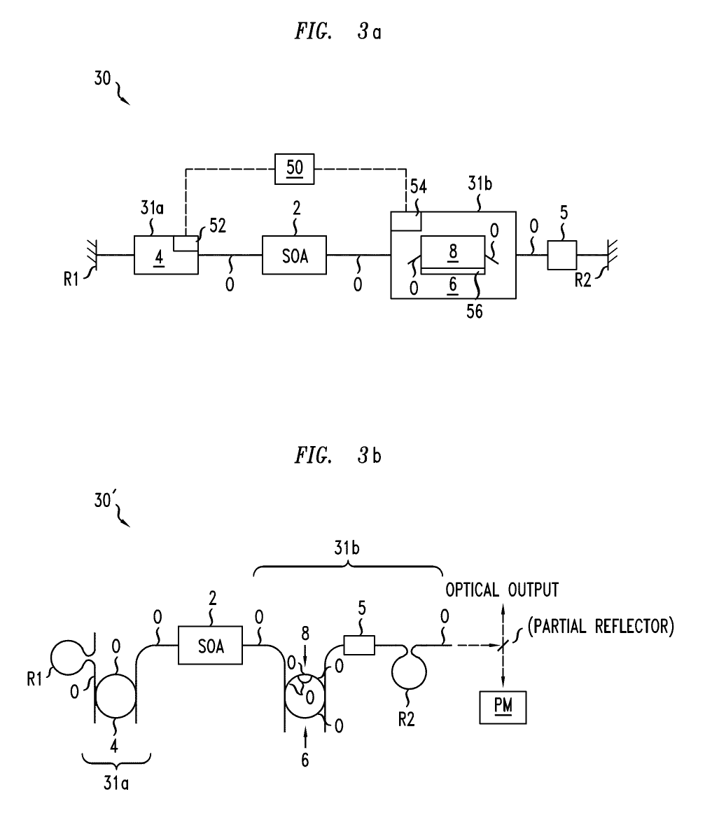

FIGS. 1a, 2a, 3a, and 4a illustrate alternate first, second, third, and fourth embodiments 10, 20, 30, 40 of lasers, e.g., internal cavity lasers or external cavity lasers. Each laser 10, 20, 30, 40 includes a laser cavity, which is formed, at least in part, by a semiconductor optical amplifier (SOA) 2 and one or more reflective optical filters 11, 21, 31a, 31b, 41, e.g., passive planar light waveguide circuit(s). The SOA 2 is an optical gain medium for the laser, e.g., an electrically pumpable gain medium, and the one or more reflective optical filters 11, 21, 31a, 31b, 41 determine and may allow selective tuning of the lasing wavelength(s) of the laser. Each reflective optical filter 11, 21, 31a, 31b, 41 optically feeds, back to the SOA2, a portion of the light received from the SOA 2. In some embodiments, the one or more reflective optical filter(s) 11, 21, 31a, 31 b, 41 do not include an optical gain medium so that these embodiments 10, 20, 30, 40 are external cavity lasers.

The combination of one or more reflective optical filters 11, 21, 31a, 31b, 41 includes a first optical ring-resonator 4 and a second optical ring-resonator 6, which are serially optically coupled together and are serially optically coupled to the SOA 2. One of the two optical ring-resonators 4, 6 has an internal optical waveguide segment formed by a Mach-Zehnder interferometer (MZI) 8. Since the MZI 8 forms an internal optical waveguide segment of the one of the two optical ring-resonators 4, 6, the MZI 8 is not part of any optical coupler connecting that one of the optical ring-resonators 4, 6 to an external light source or to an external light detector. The MZI 8 is disjoint from optical coupler(s) externally coupling this one of the optical ring-resonators 4, 6 to the other one of the optical ring-resonators 6, 4 and is disjoint from optical coupler(s) externally coupling this one of the optical ring-resonators 4, 6 to the SOA 2. Herein, portions of such optical coupler(s) coupling directly to external light source(s), external optical waveguide(s), and/or external light detector(s) are not referred to as internal parts of an optical ring-resonator.

Herein, the optical ring-resonators 4, 6 may be formed, e.g., by any closed optical loop of optical waveguide segments. The lateral shapes or layouts of the closed optical loop may take many different forms, e.g., oblong, circular, race-track shaped, serpentine shaped, etc.

The serial combination of the SOA 2 and the one or more reflective optical filters 11, 21, 31a, 31b, 41 form the optical cavity of the laser 10, 20, 30, 40, e.g., a Fabry-Perot cavity, with or without other serially coupled optical elements. The optical cavity typically includes one or two optical reflectors R1, R2. The first optical reflector R1 is located at or near a back face of SOA 2, as in FIGS. 1a, 2a, and 4a, or is located at or near a distal end of one of the reflective optical filters 31a, as in FIG. 3a, e.g., to produce a reflective double-pass optical filter. The second optical reflector R2 is located at or near the distal end or forms a distal optical segment of one of the one or more reflective optical filters 11, 21, 31b, 41, e.g., i.e., to effectively produce another reflective double-pass optical filter. Each optical reflector R1, R2 may include a metallic light reflector, a cleaved end of a planar optical waveguide, a Sagnac optical waveguide loop, or another conventional optical reflector known to those of ordinary skill in relevant arts.

Herein, an optical reflector may be any optical component that returns, back into an optical waveguide, a large fraction of the light received from the optical waveguide. e.g., 10 percent or more, 20 percent or more, or even 50% or more of the received light power. Some such optical components may or may not introduce a substantial delay to the light prior to returning the light back into the optical waveguide from which the light was received. For example, a Sagnac optical loop introduces a large delay and contributes a fraction of the optical path length of the optical cavity of a laser. Some such optical components may introduce a phase shift, but little delay, e.g., an optical reflector formed by a metal layer introduced an approximate π radian phase shift or delay. Thus, the optical reflectors R1 and R2 of FIGS. 1a, 2a, 3a, and 4a may or may not significantly contribute to the total optical path lengths of the optical cavities of the lasers 10, 20, 30, and 40.

In the first, second and third lasers 10, 20, 30, of FIGS. 1a, 2a, and 3a, the two optical reflectors R1, R2 effectively form the ends of Fabry-Perot laser cavities that form the laser cavity.

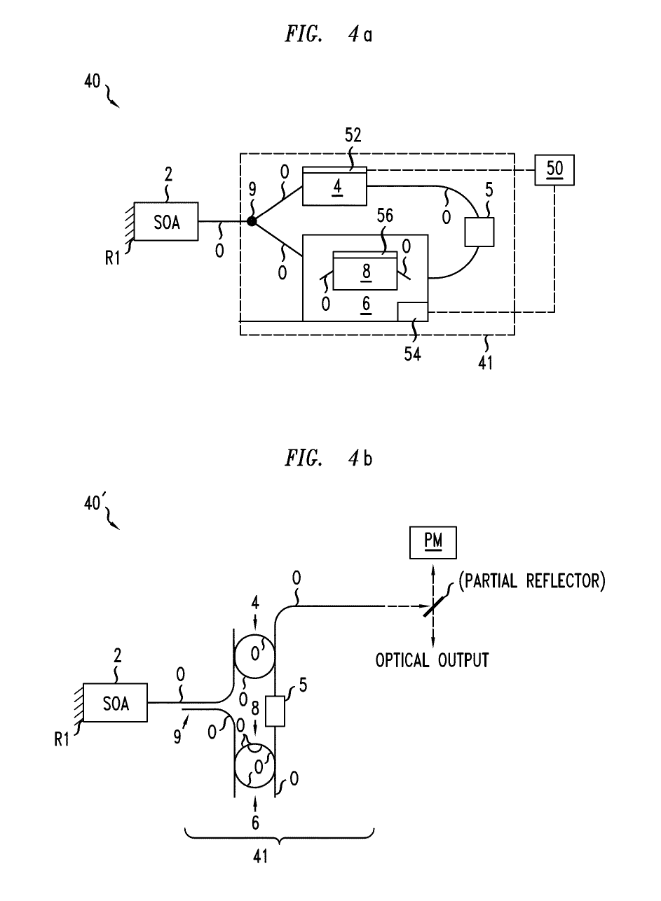

In the fourth laser 40 of FIG. 4a, the first and second optical ring-resonators 4, 6 are optically coupled to form a loop-shaped optical path that optically connects to one side of the SOA 2. The loop-shaped optical path closes the corresponding side of the laser's optical cavity, and the optical reflector R1 at or near the back face of the SOA 2 closes the other end of the laser's optical cavity. In particular, the loop-shaped optical path connects together two physically adjacent optical outputs of a conventional 1×2 optical coupler 9 whose optical input connects to a physically adjacent optical output of the SOA 2.

In some embodiments, the SOA 2 and the one or more reflective optical filters 11, 21, 31a, 31b, 41 may have optical waveguides of similar materials formed on the same or similar materials, e.g., group III-V semiconductor, optical waveguides located on a group III-V substrate such as InP.

In other embodiments, the SOA 2 and the one or more reflective optical filters 11, 21, 31a, 31 b, 41 may have optical waveguides that are formed of different materials and may or may not be formed on different substrates.

For example, the SOA 2 may have a group III-V semiconductor, optical waveguide, e.g., on an InP substrate or over a silicon substrate, and the one or more reflective optical filters 11, 21, 31a, 31b, 41 may have silica or silicon optical waveguides, e.g., on a silicon substrate.

The fabrication of the SOA 2 and the one or more reflective optical filters 11, 21, 31a, 31b, 41 of different materials and, e.g., on substrates with different thermal properties, may enable better control of spectral responses of the one or more reflective optical filters 11, 21, 31a, 31b, 41. In particular, the use of different material substrates may enable better thermal isolation so that heat generated by the SOA 2 interferes less with the temperature stabilization of the one or more reflective optical filters 11, 21, 31a, 31b, 41.

In other embodiments, the optical cavity may be formed as a single optical loop that serially connects the optical ring-resonators 4, 6 and the SOA 2 (not shown). In particular, such a loop-shaped optical cavity may physically optically connect each end of the SOA 2 to a physically neighboring end of one of optical ring-resonators 4, 6.

In some useful embodiments, the one or more reflective optical filters 11, 21, 31a, 31b, 41 may be manufactured and tuned so that the laser 10, 20, 30, 40 only lases in a single narrow and contiguous optical wavelength range. Herein, the optical wavelength range over which a laser lases is referred to as the optical linewidth of the laser. Some of the above-described embodiments of the laser 10, 20, 30, 40 have an optical linewidth of a few hundred kilo Hertz (kHz) of less, one hundred kHz or less, or even less than about fifty kHz. In particular, each optical ring-resonator 4, 6 has a series of narrow optical band passes where substantial optical feedback to the optical gain medium of the SOA 2 may be possible. Such optical wavelengths of strong optical feedback may support lasing in one or more of these narrow optical band passes. But, the one or more reflective optical filters 11, 21, 31a, 31b 41 may be fabricated and tuned so that optical feedback at only one of these narrow optical band passes supports lasing of the laser 10, 20, 30, 40.

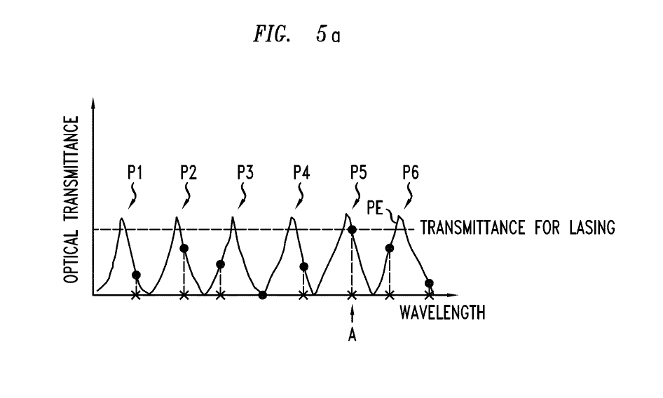

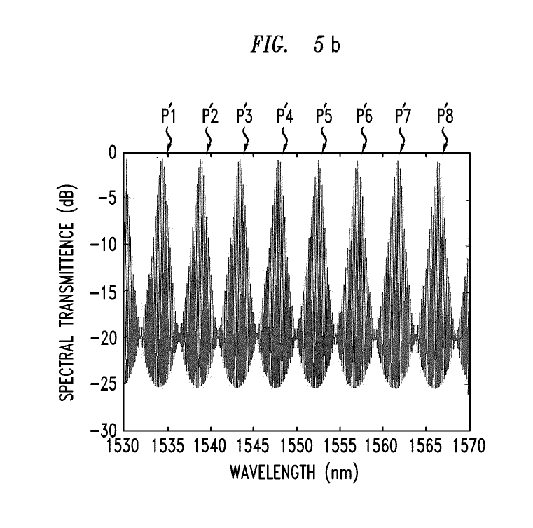

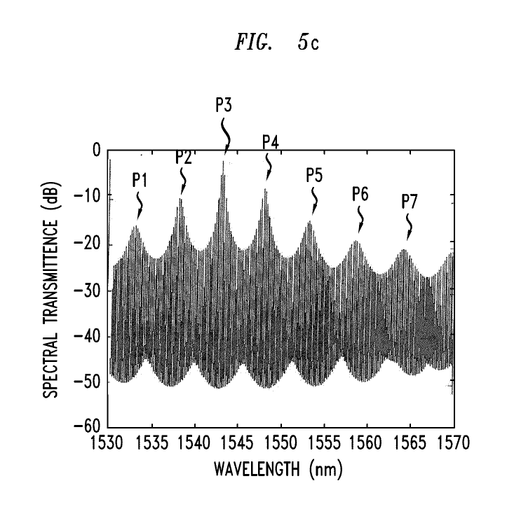

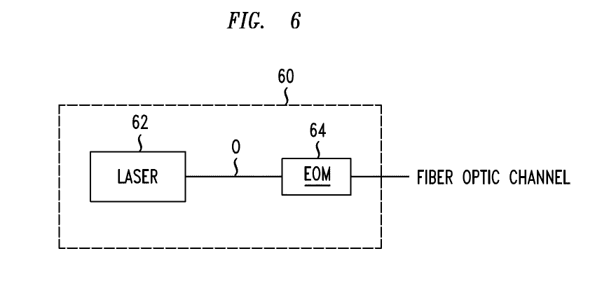

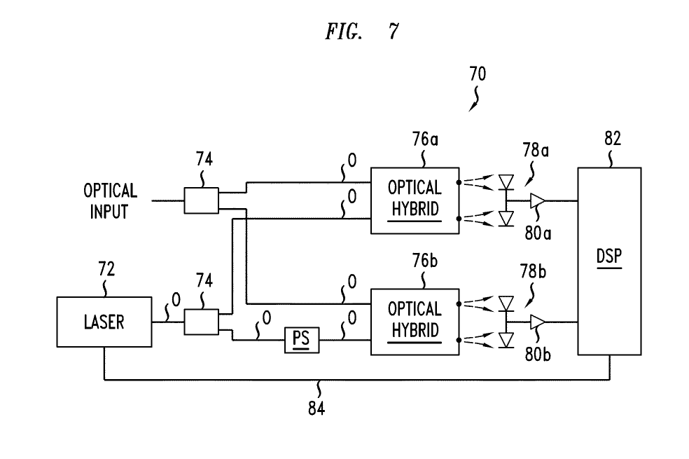

Referring again to FIGS. 1a, 2a, 3a, 4a, the external cavity lasers 10, 20, 30, 40 may also include a tunable optical phase shifter 5, e.g., a conventional electrically tunable optical phase shifter, that forms an optical path segment of the laser's optical cavity. The tunable optical phase shifter 5 can be used to adjust the total optical path length of the optical cavity of the laser 10, 20, 30, 40. In particular, the tunable optical phase shifter 5 may be used to set the total optical path length of the laser's optical cavity so that one of the laser's cavity modes have an optical wavelength that is about equal to a single selected coincidence optical wavelength between the optical band passes of the optical ring-resonators 4, 6. e.g., the peak P3 of FIG. 5c. In such a manner, the lasing optical wavelength can be better limited, e.g., to not include a portion of a neighboring optical band pass of one of the optical ring-resonators 4, 6. Indeed, the inventor believes that some embodiments of the lasers 10, 20, 30, 40 can be fabricated and tuned to lase with an optical linewidth of a few hundred kHz or less, a 100 kHz or less, or even less than 50 kHz.

The tunable optical phase shifter 5 may be located at any of a variety of segments of the optical cavity of the laser 10, 20, 30, 40. For example, the optical phase shifter 5 may be in the SOA 2, in one or more of the reflective passive optical filter(s) 11, 21, 31a, 31 b, 41, or between the SOA 2 and one reflective passive optical filter 11, 21, 31a, 31, 41. In the one or more reflective passive optical filters 11, 21, 31a, 31 b, 41, the optical phase shifter 5 may be located between the optical ring-resonators 4, 6, between one of the optical reflectors R1, R2 and one of the optical ring-resonators 4, 6, or even in one of the optical reflectors R1, R2 (e.g., on an optical waveguide segment of a Sagnac optical loop).

In some embodiments, the tunable optical phase shifter 5 and/or the control or heater electrodes 52, 54, 56 may be operable by an electronic controller 50. For example, the electronic controller 50 may be connected to control the optical phase shifter 5 and the combination of the optical ring-resonators 4, 6 to improve or stabilize the output of the laser 10, 20, 30, 40 based on feedback from an optional optical power monitor PM, as in FIGS. 1b, 2b, 3b, and 4b. The optical power monitor PM monitors light lost from an end of an optical waveguide O during operation. The electronic controller 50 may, e.g., dither the optical path length of the optical cavity with the optical phase shifter 5, and/or dither the spectral transmittance(s) of the optical ring-resonator(s) 4, 6 and the MZI 8 with one or more of the electrodes 52, 54, 56 to approximately maximize the optical power measured by the optical power monitor PM, e.g., ensuring a narrow and/or stable optical linewidth. Also, the electronic controller 50 may be configured to control the optical phase shifter 5 and/or control or heater electrodes 52, 54, 56 of the combination of the optical ring-resonators 4, 6 to support tuning and dynamical selection of the laser's output optical wavelength.

FIGS. 1b, 2b, 3b6, and 4b provide schematic illustrations of specific embodiments 10′, 20′, 30′, 40′ of the lasers 10, 20, 30, 40 of FIGS. 1a, 2a, 3a, and 4a. In particular, each of FIGS. 1b, 2b, 3b, and 4b schematically shows an example layout for optical waveguides “O” (i.e., thick solid lines) and optical waveguide couplers (i.e., intersections of the thick solid lines) in a planar lightwave circuit (PLC) embodiment of the reflective passive optical filters 11, 21, 31a, 31b, 41 of FIGS. 1a, 2a, 3a. 4a. Each example layout shows a serial combination of the two optical ring-resonators 4, 6, for which one of the optical ring-resonators 4, 6 has an internal optical waveguide segment, which is formed by the MZI 8. Each example layout illustrates the one or more optical reflectors R1. R2 located at or along distal portions of the reflective passive optical filter(s) 11, 21, 31a, 31b, 41. That is, the optical reflectors R1, R2 as illustrated as PLC optical loop reflectors, i.e., Sagnac optical loops. In other embodiments, the optical reflectors R1, R2 may be other conventional optical reflectors, which would be known to persons of ordinary skill in the relevant arts.

### Examples of Methods of Fabricating Lasers

Some methods of fabricating the lasers 10, 10′, 20, 20′, 30, 30′, 40, 40′ of FIGS. 1a-4b are described below. The resulting lasers may, e.g., be tuned according to method 100 of FIG. 9.

The methods of fabricating involve manufacturing the two optical ring-resonators 4, 6 and the MZI 8 to have desirable FSRs. These FSRs are typically not significantly changed by later tuning, because the two optical ring-resonators 4, 6 and the MZI 8 usually have total optical path lengths that are much longer that optical wavelengths for which the SOA 2 has a significant or large optical gain. As an example, the two optical ring-resonators 4, 6 and the MZI 8 may have total optical path lengths of the order of a centimeter or more, and the SOA 2 may have a significant or large optical gain only at and/or near fiber optical communication wavelengths, which are typically about or near 1.5×10⁻⁶ meters.

First, the methods of fabricating produce the two optical ring-resonators 4, 6 with FSRs selected so that their serial optical combination will have widely spaced, optical band passes, i.e., widely spaced compared to the FSRs of the individual optical ring-resonators 4, 6. The serial optical combination of two optical ring-resonators 4, 6 has optical band passes at coincidences between the optical band passes of the two individual optical ring-resonators 4, 6. A coincidence occurs when an optical pass band of one optical ring-resonator spectrally overlaps with an optical band pass of another, serially connected, optical ring-resonator. Thus, the optical band passes of the serial optical combination of the two optical ring-resonators 4, 6 are widely spaced if coincidences between their individual optical band passes are widely spectrally spaced.

The separation between neighboring ones of the coincidences is an integer multiple of the FSRs of both of the optical ring-resonators 4, 6. Thus, the coincidences can be widely spaced if the two optical ring-resonators 4, 6 are fabricated to have FSRs with close but different values. In such a configuration, many more other ones of the optical band passes of the individual optical ring-resonators 4, 6 will typically not spectrally overlap, i.e., will not coincide. Thus, the other optical band passes will not be able to cause strong optical feedback to the optical gain medium of the optical cavities of the lasers 10, 10′, 20, 20′, 30, 30′, 40, 40′.

Second, the methods of fabricating produce the MZI 8 with an FSR that is selected to conveniently spectrally modulate the strength of the optical band passes of the serial optical combination of the optical ring-resonator 4, 6. The MZI 8 defines an approximately periodic envelope PE that slowly wavelength-modulates strengths of the optical band passes of the one of the optical ring-resonator 4, 6 internally having the MZI 8. The inventor expects that the one of the optical ring-resonators 4, 6 with the internal MZI 8 will have a spectral transmittance T whose amplitude approximately satisfies:

|T|∝|1−(1−κ)H_{MZI}(λ)exp[−L_{ring}(α/2+2iπn/λ)]|⁻¹.

The above relation describes the spectral transmittance T of embodiments of an example of that one of the optical ring-resonators 4, 6 for which the optical waveguide loop transfers some light, which is received at its optical input, to its optical output prior to directing any such received light to the MZI 8. But, it is expected by the inventor that a relation having similar features will describe other embodiments in which the optical ring-resonator 4, 6 has an optical waveguide loop that directs the light, which is received at its optical input, to the MZI 8 prior to transferring any such received light to its optical output. Above, L_{ring}, α, and n define the length, optical attenuation, and effective refractive index of this optical ring-resonator 4, 6, and κ defines the optical coupling of the internal optical loop of the optical ring-resonator 4, 6 to input or output optical waveguides thereto or therefrom. Above, H_{MZI}(λ) is the spectral transmittance of the MZI 8, and λ is the optical wavelength of light.

The above relation implies that the spectral transmittance T will have optical band passes, which are spaced by the FSR of the optical ring-resonator 4, 6 having the MZI 8. In addition, the above relation for the spectral transmittance T includes a slowly spectrally varying and approximately periodic envelope PE, which modulates strengths of the series of these optical band passes in a frequency-dependent manner. The approximately periodic envelope PE is due to the dependence on H_{MZI}(λ) of the spectral transmittance T, i.e., is produced by the MZI 8. That is, the internal MZI 8 causes a modulation of strengths of the closely spaced and optical band passes of the one of the optical ring-resonators 4, 6 with the MZI 8, wherein the modulation is approximately periodic in frequency.

The approximately periodic envelope PE also spectrally modulates the total spectral transmittance and the optical feedback of the serial optical combination of the two optical ring-resonators 4, 6. In addition, while the variation of the spectral modulation may typically be small over the separation of the neighboring optical band passes of the individual optical ring-resonators 4, 6, the variation of the spectral modulation can be large over a distance of the separation of the coincidences between the optical band passes of the two optical ring-resonators 4, 6.

FIG. 5a qualitatively illustrates a hypothetical example for a desired relationship between coincidences between the optical band passes of the two optical ring-resonators 4, 6 and the approximately periodic envelope PE of the MZI 8. In FIG. 5a, locations of the coincidences between optical band passes of the first and second optical ring-resonators 4, 6 are indicated by crosses on the horizontal axis, and values of the approximately periodic envelope PE at the coincidences are indicated by solid dots. At the solid dots, these values of the approximately periodic envelope PE qualitatively indicate relative strengths of the optical feedback from the serial optical combination of the first and second optical ring-resonators 4, 6 for the corresponding coincidences.

In FIG. 5a, the approximately periodic envelope PE has a spectral periodicity that is not simply commensurate with the periodicity of coincidences. For that reason, the sequence of relative strengths of the optical feedback at the coincidences does not repeat itself. In particular, the fabrication of the optical ring-resonators 4, 6 and the MZI 8 typically involves selecting a configuration of these FSRs to ensure that these periodicities are not simply commensurate over the range in which the SOA 2 provides significant optical gain, e.g., the approximately spectrally flat part of the gain band of the SOA 2. For such a configuration, the fabrication can enable the two optical ring-resonators 4, 6 to only have a single coincidence A, at which, the optical feedback has a largest value in the significant optical gain band of the SOA 2.

One example of the above described configurations for the lasers 10, 10′, 20, 20′, 30, 30′, 40, 40′ of FIGS. 1a-4b is described below.

In the example, a first of the optical ring-resonators 4, 6 is fabricated to have its FSR, i.e., FSR₁, on a preselected grid of optical frequencies, e.g., one of the ITU's dense wavelength division multiplexing (DWDM) grids. Then, lasing will also be constrained to be on said preselected grid. For example, methods of fabrication may fix the FSR₁ to be on the 12.5 GHz, 25 GHz, 50 GHz, or 100 GHz grid.

In the example, the second of the optical ring-resonators 6, 4 is fabricated to have its FSR, i.e., FSR₂, close in value to but different from the value of the FSR₁ of the first of the optical ring-resonators 4, 6. Then, the spacing of coincidences between the optical band passes of the two optical ring-resonators 4, 6 will be much larger than the spacing of the optical band passes of the individual optical ring-resonators 4, 6 themselves.

For example, methods of fabrications may fix the value of the FSR₁ to be about 25 GHZ and the FSR₂ to be 24 GHz. Then, the coincidences between the optical band passes of the two optical ring-resonators 4, 6 should be spaced apart by about 24×25 GHz=600 GHz, i.e., about 5 nm. Such a spacing is large compared to the spacing of 24 GHz or 25 GHz between the optical band passes the exemplary individual optical ring-resonators 4, 6.

In the example, the MZI 8 is fabricated to have an FSR, i.e., FSR_{MZI}, for which only one coincidence between the optical band passes of the two optical ring-resonators 4, 6 may coincide with a peak in the approximately periodic envelope PE of the MZI 8 in the range of significant optical amplification of the SOA 2. For example, if N is the number of coincidences between such optical band passes in the range of significant optical amplification of the SOA 2, and D is the distance between neighboring ones of the coincidences, the FSR_{MZI} may satisfy (N−1)×FSR_{MZI}=N×D. For the above example of a spacing of about 5 nm between such coincidences and a 40 nm range for significant optical amplification in the SOA2, the FSR of the MZI 8, i.e., FSR_{MZI}, could, e.g., satisfy 7×FSR_{MZI}=8×D. For such a selection of fabrication parameters, only a single contiguous and narrow optical pass band would typically be potentially available for lasing in the lasers 10, 10′, 20, 20′, 30, 30′, 40, 40′ of FIGS. 1a-4b.

FIG. 5b and 5c illustrate simulated spectral transmittances of an example of the above-described configurations for the optical ring-resonators 4, 6 of FIGS. 1a-4b.

FIG. 5b illustrates the spectral transmittance of the optical ring-resonator 4, 6 with the MZI 8 on an internal optical waveguide segment thereof. The spectral transmittance has a series of peaks P′1, P′2, P′3, P′4, P′5, P′6, P′7, P′8 and valleys, which are separated by about 0.2 nanometers (nm) to 0.3 nm. The FSR of this one of the optical ring-resonators 4, 6 is about 24 to 25 GHz. The heights of the peaks P′1-P′8 are slowly and strongly intensity modulated as the wavelength varies over a period of about 4 nm, i.e., by the approximately periodic envelope PE produced by the MZI 8. The wavelength-dependent intensity modulation, e.g., via the peaks P′1-P′8, is believed by the inventor to be much stronger than the modulation would otherwise typically result if the MZI 8 were instead located at an external optical port of one of the optical ring-resonators 4, 6. The inventor believes that the stronger intensity modulation results, because much light makes multiple circulations around the closed optical path of the one of the optical ring-resonators 4, 6 with the MZI 8 and is thus, modulated by the MZI 8 multiple times.

FIG. 5c illustrates a simulated spectral transmittance for a particular tuning of a serial optical combination of the optical ring-resonator 6, 4 when the one of the optical ring-resonators 4, 6 with the MZI 8 has a spectral transmittance approximately as shown in FIG. 5b. The spectral transmittance of the serial optical combination also has a series peaks at the optical wavelengths of optical band passes of the individual optical ring-resonators 4, 6. But, the series of these peaks is intensity modulated over a wavelength range of about 4 nm to 5 nm thereby producing a series of seven local largest peaks, i.e., between 1530 nm and 1570 nm. The optical wavelengths of the local largest peaks P1, P2, P3, P4, P5, P6, P7 correspond to the coincidences between the optical band passes of the two individual optical ring-resonators 4, 6. In addition, the height of these local largest peaks P1-P7 is wavelength-modulated so that one of the local largest peaks P3 is a global largest peak in the illustrated wavelength range of 1530 nm to 1570 nm. The modulation of local largest peaks P1-P7, which has a nontrivial wavelength-dependence, results, because the approximately periodic envelope PE produced by the MZI 8 has a periodicity that differs from the spacing of the coincidences, i.e., by not being simply commensurate. For that reason, such a serial optical combination of optical ring-resonators 4, 6 may be tuned, e.g., as illustrated below in FIG. 9, to enable lasing only in a single narrow and contiguous optical wavelength band at and near the largest peak P3 when the optical gain media only provides substantial gain in the 1530 nm to 1570 nm optical wavelength range.

The above-described configurations of lasers 10, 10′, 20, 20′, 30, 30′, 40, 40′ may offer advantages such as providing thermally stable configurations and/or being simply tunable for lasing in narrow and contiguous optical wavelength band, e.g., for use in coherent optical sources. In particular, operation of such embodiments of the lasers 10, 10′, 20, 20′, 30, 30′, 40, 40′ as narrow and contiguous, optical, wavelength-band sources typically may require a high finesse tuning of the coincidences of two optical ring-resonators 4, 6 and a simpler tuning of the MZI 8, e.g., as described below.

Examples of Methods of Tuning and/or Operating Lasers

FIG. 9 illustrates a method 100 for pre-tuning, dynamically tuning, and/or operating a laser whose optical cavity has a serial optical combination of first and second optical ring-resonators, wherein one of the optical ring-resonators has an internal optical waveguide segment formed by an MZI. In FIG. 9, optional steps are enclosed in dashed boxes. As previously discussed, the optical ring-resonators may be fabricated to have close and different FSRs. Similarly, as previously discussed, the approximate periodicity of the spectral transmittance of the MZI may be simply incommensurate with the spacing of the coincidences between the optical band passes of the individual optical ring-resonators over the significant gain band of the laser's optical amplification medium. The method 100 may be performed to tune and/or operate some embodiments of the lasers 10, 10′, 20, 20′, 30, 30′, 40, 40′ of FIGS. 1a-4b, e.g., to produce a lasing in a spectrally narrow and contiguous optical band.

In FIG. 9 optional steps and/or relations between steps are shown by dashed lines.

The method 100 includes tuning the MZI to shift wavelength(s) of peaks in the spectral transmittance of the MZI (step 102). The tuning step 102 shifts the peaks of the approximately periodic envelope by which the MZI modulates strengths of the optical band passes of the optical ring-resonator with the MZI, e.g., shifts the peaks P′1-P′8 of FIG. 5a. The tuning step 102 may be performed by varying the optical refractive index of one or more optical waveguide segments of the internal optical arms of the MZI, e.g., with an electrically controlled, optical phase shifter. In various embodiments, the optical phase shifter may change the index, e.g., by heating or by carrier injection, i.e., in semiconductor optical waveguides. During the tuning step 102, the difference between the optical path lengths of the two internal optical arms of the MZI is changed, e.g., by less than the wavelength of light to be processed by the MZI. The tuning step 112 typically does not significantly change the FSR of the MZI, because the MZI's internal optical arms are typically much longer than the wavelength of the light being processed.

Typically, the laser has a potential for lasing only near to the peaks in the spectral transmittance of the MZI, because the serial optical combination of the optical ring-resonators can only provide a substantial optical feedback to the laser's optical gain medium near such peaks. Thus, the tuning step 102 involves effectively selecting a set of optical wavelength ranges for potential lasing from the larger range in which the optical gain medium of the laser provides significant optical gain, e.g., selecting a small range about each individual peak P′1-P′8 in FIG. 5a.

The method 100 includes tuning the serial optical combination of the first and second optical ring-resonators to have a coincidence between their optical band passes at or near one of the peaks in the spectral transmittance of the MZI (step 104). Typically, the laser will only have a potential to lase at optical wavelengths near the coincidence, which is located at or near the one of the peaks of the spectral transmittance of the MZI, because the spectral transmittance of the serial optical combination of the optical ring-resonators will be largest at such optical wavelengths. Typically, the tuning step 104 causes only a single one of the coincidences to be located at near such a peak, because the optical ring-resonators have been fabricated so that the spacing between such peaks and the spacing between such coincidences are not commensurate over the region of substantial or significant optical amplification for the laser's optical gain medium. Then, the serial optical combination of the optical ring-resonators may only produce optical feedback at or near the lasing threshold in a narrow and contiguous optical pass band at one coincidence.

In some embodiments, the tuning step 104 may include sub-step A and sub-step B.

Sub-step A involves tuning one of the optical ring-resonators to shift its optical band passes to be on a pre-selected optical channel grid, e.g., one of the ITU DWDM grids for optical communication channels. Thus, the sub-step A configures the laser to be constrained to lase on said pre-selected optical channel grid, because coincidences between the two optical ring-resonators are also at optical band passes of the one of the optical ring-resonator.

Sub-step B involves tuning the other of the optical ring-resonators to shift its optical band passes such that one coincidence between the optical band passes of the two optical ring-resonators is at or near one of the peaks in the spectral transmittance of the MZI. The sub-step B effectively selects the optical wavelength for lasing to be the optical wavelength of that one of the coincidences, because the optical feedback of the serial optical combination of the optical ring-resonators will typically be largest at that one coincidence.

The sub-steps A and B may be performed by tuning optical phase shifters located in the individual optical ring-resonators being tuned in the sub-steps A and B. Such tuning typically does not significantly change FSRs of the optical ring-resonators, because these optical devices typically have internal optical loops that are much longer than the optical wavelength of the light being processed during operation of the laser.

The method 100 may optionally include adjusting the optical path length of the laser's optical cavity such that one laser cavity mode has the optical wavelength of that coincidence of the optical band passes of the optical ring-resonators, which is tuned to be at or near one peak in the spectral transmittance of the MZI (step 106). The adjusting step 106 may be performed by operating an optical phase shifter serially optically coupled to the optical ring-resonators and the laser's optical gain medium, e.g., the optical phase shifter 5 of FIGS. 1a-4b. The tuning step 106 configures the laser for lasing at the optical wavelength of the coincidence selected by the tuning steps 102 and 104.

The method 100 may also optionally include electrically or optically pumping the optical gain medium of the laser to cause the laser to lase at the optical wavelength of the coincidence selected by the steps 102 and 106 (step 108). In some embodiments, the optical gain medium may be electrically pumpable to cause the laser to lase. For example, the optical gain medium may be located in the SOA 2 of FIGS. 1a-4b. In other embodiments, the optical gain medium may be optically pumpable to cause lasing. For example, the optical gain medium may be located in a rare-earth doped optical waveguide, e.g., an erbium-doped optical fiber.

In various embodiments, the order of the steps 102, 104, 106, and 108 may be differ. In some embodiments, it may be useful to perform the pumping step 108 first so that an optical power of the laser may be monitored during the tuning and/or adjusting steps 102, 104, and/or 106. In other embodiments, the tuning and adjusting steps 102, 104, and 106 may be performed, e.g., based on look up table values of tuning and adjustment voltages and/or currents, prior to performing the pumping step 108, e.g., so that undesired light is output by the laser.

The tuning and adjusting steps 102, 104, and 106 of the method 100 may be performed, e.g., by the electronic controller 50 of FIGS. 1a-4b. The electronic controller 50 may dynamically tune current(s) to or voltages across the control or heater electrode(s) 52, 54 located along optical waveguide segment(s) of the optical loop of one or both of the optical ring-resonators 4, 6. Each electrode 52, 54 can be tuned to shift the series of narrow optical band passes of the corresponding optical ring-resonator 4, 6 by changing the optical refractive index and optical path length of a corresponding optical waveguide segment. Similarly, the electronic controller 50 may dynamically tune the voltage across or current to the control or heater electrode(s) 56 located along one or more segments of the internal optical arms of the MZI 8. The electrode(s) 56 can be tuned to shift the spectral transmittance spectrum of the MZI 8 by changing the optical refractive index and optical path length of the one or more segments of the internal optical arms. Also, the electronic controller 50 may dynamically tune the voltage across or current to the electrode(s) that operates the optical phase shifter 5. i.e., to adjust the total optical path length of the laser's optical cavity. The electronic controller 50 may be configured to control and/or dynamically tune other types of well-known optical phase shifters for the elements 52, 54, 56, and 5 along optical waveguide segments of the optical ring-resonator(s) 4, 6; internal optical arm(s) of the MZI 8; and/or the laser's optical cavity.

Alternately, the tuning and/or adjusting steps 102, 104, 106 of the method 100 may operate piezoelectric device(s) to mechanically distort optical waveguide(s) and/or to relatively move facing ends of optical waveguides to adjust optical path length(s). For example, the electronic controller 50 may use such mechanical methods in the optical phase shifter 5 to change the total optical path length of the laser's optical cavity and/or use the control electrode(s) 52, 54, 56 to cause such mechanical methods to shift the optical pass bands of the optical ring-resonator(s) 4, 6 and/or to shift the peaks of spectral transmittance of the MZI 8 of FIGS. 1a-4b.

### Examples of Systems Including One or More Lasers

FIG. 6 illustrates an optical data transmitter 60 that includes a laser 62, e.g., one of the lasers 10, 10′, 20, 20′, 30, 30′, 40, 40′ of FIGS. 1a-4b. The optical transmitter 60 also includes an external optical modulator 64, which is configured to modulate a digital data stream onto a light carrier emitted by the laser 62. For example, the modulation may be produced by optical phase and/or amplitude modulation of the light carrier according to any of a variety of formats, e.g., ON/OFF keying (OOK), binary phase-shift-keying (PSK), quadrature PSK, 8 quadrature amplitude modulation (QAM), 16 QAM format or another modulation format having a larger optical constellation such as 16 QAM, 32 QAM, 64QAM, etc. In some embodiments, the optical data transmitter 60 may output to the optical fiber channel, a data-modulated optical carrier, which has a very stable wavelength, optical-carrier. For example, the optical carrier's wavelength may be very stable if the laser 62 is configured to only emit laser light in a single narrow and contiguous, optical, wavelength band, e.g., as already discussed with respect to embodiments of the external cavity lasers 10, 10′, 20, 20′, 30, 30′, 40, 40′ of FIGS. 1a-4b. A stable optical carrier wavelength may be advantageous in some coherent optical communications systems. For example, if the laser 62 has a stable and narrow optical linewidth, a coherent optical data receiver may be able to feedback lock the optical wavelength of its local optical oscillator to the optical carrier wavelength of the optical data transmitter 60.

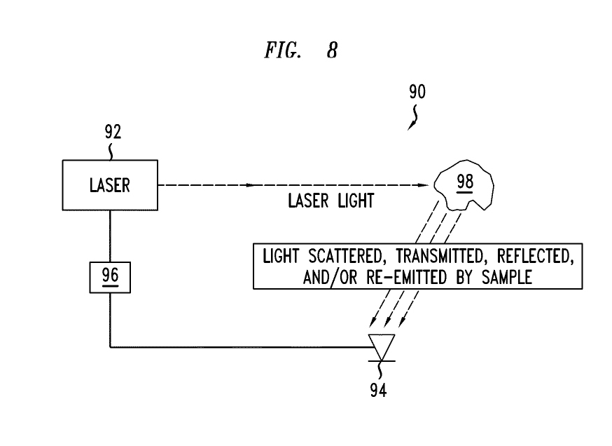

FIG. 7 illustrates a coherent optical data receiver 70 that includes a laser 72, e.g., one of the lasers 10, 10′, 20, 20′, 30, 30′, 40, 40′ of FIGS. 1a-4b, which may be used in a fiber optical communication system, e.g., together with the optical data transmitter 60 of FIG. 6. The coherent optical data receiver 70 also includes optical splitters 74, optical hybrid(s) 76a, 76b; balanced pair(s) of photodiode detectors 78a, 78b for differential detection; electronic amplifier(s) and analog-to-digital converter(s) 80a, 80b, and a digital signal processor (DSP) 82.

In the coherent optical data receiver 70, the laser 72 functions as a local optical oscillator whose light is optically mixed with the received data-modulated optical carrier in the optical hybrid(s) 76a, 76b, e.g. optically mixed with a relative phase of about 0 radians and also with a relative phase shift of about π/2 radians due to an optical phase shifter (PS). Such optical mixing enables the detection of both amplitude and phase modulations of the data-modulated optical carrier, e.g., in-phase and quadrature phase modulations, in the received data-modulated optical carrier, e.g., as received at the optical input of 1×2 optical splitter 74.

In some embodiments, the laser 72 may have a very stable and narrow optical linewidth, e.g., if configured or tuned as described with respect to the lasers 10, 10′, 20, 20′, 30, 30′, 40, 40′ of FIGS. 1a-4b. For some such embodiments, the coherent optical data receiver 70 may include an electronic feedback loop 84 enabling the DSP 82 to dynamically tune the output optical wavelength of the laser 72 based on the digital data stream demodulated by the DSP 82, e.g., to produce an optical phase-locked loop. Such a feedback control of a local optical oscillator may be advantageous to a coherent optical data receiver configured to demodulate a digital data stream from an optical carrier modulated via a phase shift keying format, i.e., by any modulation format mentioned with respect to FIG. 6.

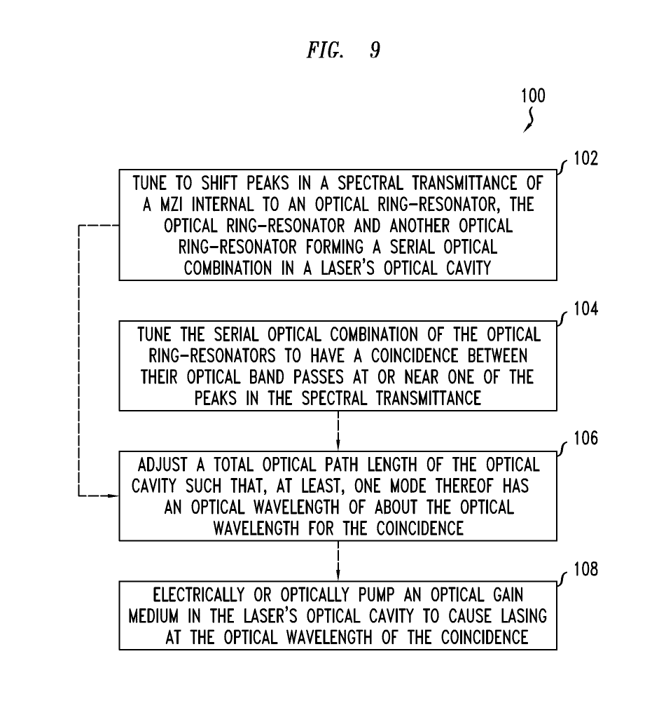

FIG. 8 illustrates an optical spectrum analyzer 90 that includes one or more lasers 92, e.g., any of the lasers 10, 10′, 20, 20′, 30, 30′, 40, 40′ of FIGS. 1a-4b. The optical spectrum analyzer 90 also includes an optical detector 94, e.g., which includes one or more optical intensity detectors such as photodiodes, and a digital data processor 96. The laser 92 is able to illuminate a sample 98 to-be-analyzed with laser light, e.g., for a chemical spectrum. The optical detector 94 is located to receive a part of the light, which is scattered, transmitted, and/or reflected by the sample 98 in response to being illuminated by light from the one or more lasers 92, and to measure the intensity, wavelength, and/or polarization of said received light. The optical detector 94 is configured to output electronic, wireless, or optical signal(s) indicative of the measured intensities, wavelengths, and/or polarizations of the light received thereat. The digital data processor 96 is configured to receive said signal(s) indicative of the measured intensities, wavelengths, and/or polarizations from the optical detector 94 and may be configured to electrically, wirelessly, or optically control the laser 92. For example, the digital data processor 96 may be configured to cause the laser 92 to sweep its output optical wavelength, in time, so that the optical detector 94 can measure the intensity, wavelength, and/or polarization of light scattered, transmitted, or reflected by the sample 98 as a function of optical wavelength of the probing light for the laser 92. In some embodiments, the laser 92 may be tunable or configurable to output light with a very narrow optical linewidth, e.g., if controlled as already described with respect to some embodiments of the lasers 10, 10′, 20, 20′, 30, 30′, 40, 40′ of FIGS. 1a-4b. For example, the laser 92 may be operated as a wavelength-sweepable, narrow optical linewidth, excitation source, which may be advantageous for some embodiments of the optical spectrum analyzer 90.

Referring again to FIG. 9, the method 100 may include operating the laser in an optical data transmitter, a coherent optical data receiver, or an optical spectrum analyzer, e.g., as illustrated in FIGS. 6, 7, and 8.

For example, the method 100 may include modulating light emitted by the laser in the optical data transmitter 60 of FIG. 6, to produce a phase and/or amplitude modulated optical carrier for use in transmitting a digital data stream over a fiber optical communication channel.

For example, the method 100 may include mixing light emitted by the laser with a phase and/or amplitude modulated optical carrier to perform coherent detection of the data stream carried by the phase and/or amplitude modulated optical carrier in the coherent optical data receiver 70 of FIG. 7.

For example, the method 100 may include dynamically re-tuning at least one of the optical ring-resonators 4, 6 and/or the MZI 8 of FIGS. 1a-4b at a series of times such that the laser sweeps its output optical wavelength through a series of values. Such temporal sweeping of the lasing optical wavelength may be performed in the optical spectrum analyzer 90 of FIG. 8 to enable measurements of an optical absorption, an optical transmission, and/or an optical reflection spectrum of a chemical sample illuminated by the laser light.

Herein, components labeled as “processor” and “electronic controller” may be provided through the use of dedicated electronic hardware or electronic hardware configured to execute software in association with the appropriate software. Moreover, use of the term “processor” or “electronic controller” should not be construed to refer exclusively to electronic hardware capable of executing software, and may include, without limitation, digital signal processor (DSP) hardware, network processor, application specific integrated circuit (ASIC), field programmable gate array (FPGA), read only memory (ROM) for storing software, random access memory (RAM), and other non-volatile data storage devices.

The inventions are intended to also include other embodiments that would be obvious to one of skill in the art in light of the description, figures, and claims.

What is claimed is:

1. An apparatus, comprising:
a laser including an optical gain medium and first and second optical ring-resonators, the optical gain medium and the optical ring-resonators being serially optically connected together to form one or more segments of an optical cavity of the laser, and
wherein one of the optical ring-resonators has an internal optical waveguide segment formed by a Mach-Zehnder interferometer.

2. The apparatus of claim 1, wherein the laser further includes a semiconductor optical amplifier, the optical gain medium being located in the semiconductor optical amplifier.

3. The apparatus of claim 2, wherein an optical waveguide of one or both of the optical ring-resonators is a dielectric optical waveguide.

4. The apparatus of claim 1, further comprising a controller capable of tuning one or both of the first and second optical ring-resonators such that the first and second optical ring-resonators have some coincident optical band passes and some non-coincident optical band passes.

5. The apparatus of claim 4, wherein the laser further includes a semiconductor optical amplifier, the optical gain medium being located in the semiconductor optical amplifier.

6. The apparatus of claim 5, wherein an optical waveguide of one or both of the optical ring-resonators is a dielectric optical waveguide.

7. The apparatus of claim 1, further comprising a coherent optical data receiver comprising the laser and being configured to determine a digital data stream carried by a data-modulated optical carrier that is at least phase modulated, in part, by optically mixing light of the data-modulated optical carrier with light emitted by the laser.

8. The apparatus of claim 7, wherein the coherent optical data receiver is configured to feedback control an output wavelength of the laser based on measurements of the optically mixed light.

9. The apparatus of claim 1, further comprising an optical data transmitter including the laser and an external optical modulator.

10. The apparatus of claim 1, further comprising a spectral analyzer including the laser and an optical detector, the optical detector being configured to measure one or more intensities of light directed to the optical detector by a sample in response to being illuminated by light of the laser.

11. The apparatus of claim 10, wherein the spectral analyzer is capable of causing the laser to sweep, in time, an output wavelength of the laser.

12. A method, comprising:
tuning a Mach-Zehnder interferometer to wavelength-shift peaks in a spectral transmittance of the Mach-Zehnder interferometer, the Mach-Zehnder interferometer forming an internal optical waveguide segment of a first optical ring-resonator, the first optical ring-resonator and a second optical ring-resonator being a serial optical combination in an optical cavity of a laser; and
tuning the serial optical combination of the optical ring-resonators to wavelength-shift a coincidence between optical band passes of the optical ring-resonators to be located at or near one of the peaks in the spectral transmittance of the Mach-Zehnder interferometer.

13. The method of claim 12, wherein the tuning the serial optical combination includes tuning one of the optical ring-resonators to shift its optical band passes to be on a pre-selected optical channel grid.

14. The method of claim 13, wherein the preselected optical channel grid is one of the ITU grids for optical communication channels of dense wavelength-division multiplexing.

15. The method of claim 13, further comprising adjusting a total optical path length of the optical cavity such that a cavity mode thereof has an optical wavelength at about the optical wavelength of the coincidence of the optical band passes.

16. The method of claim 12, further including electrically pumping an optical medium in the optical cavity such that the laser emits light, the optical gain medium being located in a semiconductor optical amplifier.

17. The method of claim 12, further comprising mixing a portion of light emitted by the laser with a received phase and/or amplitude modulated optical carrier to perform coherent detection of the phase-modulated optical carrier in a coherent optical receiver.

18. The method of claim 12, further comprising then, data modulating light emitted by the laser in an optical data transmitter to produce a modulated optical carrier.

19. The method of claim 12, further comprising re-tuning one or more of the first optical ring-resonator, the second optical ring-resonator and the Mach-Zehnder interferometer such that a wavelength of light emitted by the laser sweeps, in time, through a series of values.

20. The method of claim 19, further comprising measuring intensities of light transmitted, reflected, or scattered by a sample in response to the sample being illuminated by the emitted light at the values of the wavelength of light emitted.
